(19) United States
(12) Patent Application Publication
(10) Pub. No.: US 2025/0012373 A1
(43) Pub. Date: Jan. 9, 2025

(54) FLUID-FLOW CONTROL DEVICE

(71) Applicant: HAM-LET (Israel-Canada) Ltd, Nof Hagalil (IL)

(72) Inventors: Boris MARGOL, Nof Hagalil (IL); Shaya MAYZELS, Nof Hagalil (IL); Arik MIMRAN, Nof Hagalil (IL)

(73) Assignee: HAM-LET (Israel-Canada) Ltd, Nof Hagalil (IL)

(21) Appl. No.: 18/777,226

(22) Filed: Jul. 18, 2024

Related U.S. Application Data
(62) Division of application No. 17/629,329, filed on Jan. 21, 2022, now abandoned.

(30) Foreign Application Priority Data
Jul. 24, 2019 (IL) 268254

(51) Int. Cl. F16K 31/00; F16K 7/12; F16K 7/14; F16K 31/122

(52) U.S. Cl. CPC F16K 31/006; F16K 7/126; F16K 7/14; F16K 31/007; F16K 31/1221

(57) ABSTRACT

A process fluid-flow control device comprising: an inlet, an outlet, an actuation mechanism and a diaphragm; wherein: the diaphragm is in direct operational communication with the outlet and/or the inlet; the mechanism comprises a driving piezoelectric component, and the device is configured to allow: employing the driving piezoelectric component to adjust force exerted on the diaphragm and thereby regulating flow of the process fluid through the device within a first rate range.

### CROSS-REFERENCE TO RELATED APPLICATIONS

This application is a divisional application of U.S. patent application Ser. No. 17/629,329, filed on Jan. 21, 2022, which is a national stage application under 35 U.S.C. § 371 of International Application No. PCT/IL2020/050822, filed on Jul. 23, 2020, which claims priority benefit of Israeli Patent Application No. 268254, filed on Jul. 24, 2019. All disclosures of the documents named above are incorporated herein by reference.

### BACKGROUND

A mass flow controller (MFC) is a device used to measure and control the flow of liquids and gases. A mass flow controller is designed and calibrated to control a specific type of liquid or gas at a particular range of flow rates. The MFC can be given a set point from 0 to 100% of its full scale range but is typically operated in the 10 to 90% of full scale where the best accuracy is achieved. The device will then control the rate of flow to the given set point. MFCs can be either analogue or digital. A digital flow controller is usually able to control more than one type of fluid whereas an analogue controller is limited to the fluid for which it was calibrated.

All mass flow controllers have an inlet port, an outlet port, a mass flow sensor and a proportional control valve. The MFC is fitted with a closed loop control system which is given an input signal by the operator (or an external circuit/computer) that it compares to the value from the mass flow sensor and adjusts the proportional valve accordingly to achieve the required flow. The flow rate is specified as a percentage of its calibrated full scale flow and is supplied to the MFC as a voltage signal.

Mass flow controllers require the supply gas or liquid to be within a specific pressure range. Low pressure will starve the MFC of fluid and cause it to fail to achieve its set point. High pressure may cause erratic flow rates.

### SUMMARY

According to one aspect fluid-flow control devices are provided, that each includes an actuation mechanism having a driving piezoelectric component. Such devices are for example MFCs.

The novel devices may significantly improve the response time of fully performing instructions to alter the flow for the fluid passing through the devices.

These devices may also provide an improved ability to precisely set any flow rate in a range of preset values for the fluid passing through the devices, rather than, in some commercially available MFCs, only endpoints for the range, by on/off settings.

Some device embodiments include a plurality of actuation mechanisms, wherein at least one of the actuation mechanisms includes a driving piezoelectric component.

According to one aspect, a process fluid-flow control device is provided comprising:
an inlet, an outlet, an actuation mechanism and a diaphragm;
wherein:
the diaphragm is in direct operational communication with the outlet and/or the inlet;
the mechanism comprises a driving piezoelectric component, and the device is configured to allow:
employing the driving piezoelectric component to adjust force exerted on the diaphragm and thereby regulating flow of the process fluid through the device within a first rate range.
A high-purity gas line for example may comprise the device.

In some embodiments the driving piezoelectric component is selected from a group consisting of: stack-type driving piezoelectric component, and flexure-type driving piezoelectric component.

In some embodiments the mechanism further comprises at least one non-piezoelectric driving component in direct operational communication with the diaphragm, wherein the device is further configured to allow:
employing the driving piezoelectric component to adjust force exerted on the non-piezoelectric driving component, and
the at least one non-piezoelectric driving component to apply force on the diaphragm and thereby reducing or shutting off flow of the process fluid through the device.

In some embodiments the at least one non-piezoelectric driving component comprises a piston.

In some embodiments wherein the device is normally open, the device further comprising pneumatic means for applying force on the at least one non-piezoelectric driving component, thereby shutting flow through the device.

In some embodiments the piston has a first end in contact with the diaphragm and a second end in contact with the piezoelectric driving component.

In some embodiments the second end in contact with a free end of the piezoelectric driving component,

wherein the piezoelectric driving component is a flexure-type.

In some embodiments the device is normally closed, the device further comprising pneumatic means for applying force on the at least one non-piezoelectric driving component,

wherein the device is configured to allow employing the piezoelectric component to allow flow of pressurized air via pneumatic means to the at least one non-piezoelectric driving component and thereby allowing flow of the process fluid through the device.

In some embodiments the at least one non-piezoelectric driving component comprises a hollow piston, having a top part adjacent to the driving piezoelectric component and snugly enclosed in a barrel;
wherein when the driving piezoelectric component is not employed the driving piezoelectric component blocks the barrel and thus prevents passage of pressurized air via the piston.

In some embodiments when the driving piezoelectric component is employed the pressurized air pushes against a spring that is pressing the piston against the diaphragm and thus allows flow of the process fluid through the device.

Some embodiments further comprise means for measuring a first location of the piston, and according to the measured location employing the driving piezoelectric component to adjust the location of the piston to a second predetermined location, thereby adjusting flow of the process fluid through the device to a predetermined desired flow.

According to another aspect a kit is provided comprising any of the devices defined a bove and at least one replacement actuation mechanism comprising a replacement driving piezoelectric component,

wherein the device is configured to allow employing the at least one replacement driving piezoelectric component to regulate flow of the fluid through the device within a rate range that is not the first rate range.

According to yet another aspect a method is provided for control of fluid flow from an inlet to an outlet, the method comprising:
providing a diaphragm in direct operational communication with the outlet and/or inlet;
providing a driving piezoelectric component;
employing the driving piezoelectric component to adjust force exerted on the diaphragm and thereby regulating flow of the fluid through the device within a first rate range.

Some embodiments further comprise:
providing at least one non-piezoelectric driving component in direct operational communication with the diaphragm;
employing the driving piezoelectric component to adjust force exerted on the non-piezoelectric driving component, and
subsequently the at least one non-piezoelectric driving component applying force on the diaphragm and thereby reducing or shutting off flow of the fluid through the device.

Some embodiments further comprise:
applying pressurized air on the at least one non-piezoelectric driving component, thereby shutting fluid flow from the inlet to the outlet.

Some embodiments further comprise:
applying pressurized air on the at least one non-piezoelectric driving component;
employing the piezoelectric component to allow flow of pressurized air to the at least one non-piezoelectric driving component and thereby allowing fluid flow from the inlet to the outlet.

Some embodiments further comprise:
measuring a first location of the non-piezoelectric driving component;
employing the driving piezoelectric component according to the measured location to adjust the location of the piston to a second predetermined location, thereby adjusting the flow of the fluid from the inlet to the outlet to a predetermined desired flow.

Some embodiments further comprise:
measuring a mass flow of the fluid from the outlet;
comparing the measured mass flow with a predetermined desired mass flow from the outlet, and
employing the driving piezoelectric component to adjust force exerted on the diaphragm and thereby adjust the flow of fluid from the outlet to the desired mass flow.

This summary is provided to introduce a selection of concepts in a simplified form that are further described below in the Brief Description of the Figures and the Detailed Description. This summary is not intended to identify key features or essential features of the claimed subject matter, nor is it intended to be used to limit the scope of the claimed subject matter.

### BRIEF DESCRIPTION OF THE FIGURES

The figures illustrate generally, by way of example, but not by way of limitation, various embodiments discussed in the present document.

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

The number of elements shown in the Figures should by no means be construed as limiting and is for illustrative purposes only.

FIG. 1 schematically shows a prior art MFC;

FIG. 2 depicts a schematic block drawing of a MFC with a driving piezoelectric component;

FIG. 3a illustrates in perspective view a prior art stack-type driving piezoelectric component;

FIG. 3b presents a perspective view of a valve including the stack-type driving piezoelectric component.

FIG. 4a illustrates in perspective view a prior art flexure-type driving piezoelectric component as the component is typically commercially available, with an elastic cover;

FIG. 4b depicts in perspective view the component with the cover removed;

FIG. 4c illustrates in side view the movement of the prior art driving piezoelectric component anchored to a surface;

FIG. 5a depicts in side view an MFC device comprising a driving piezoelectric flexure-type component which is part of an actuation mechanism for the device, wherein the device is NO (Normally Open), the device being in an open state,

FIG. 5b shows the device depicted in FIG. 5a in a closed state;

FIG. 6a illustrates in a partially cut-out side view a NC (Normally Closed) device with pneumatic means that include a piston, and a driving piezoelectric flexure-type component to adjust the location of the piston, thereby adjusting the flow of the fluid through the device to a predetermined desired flow. The device is in a closed state.

FIG. 6b shows the device illustrated in FIG. 6a in an open state.

### DETAILED DESCRIPTION

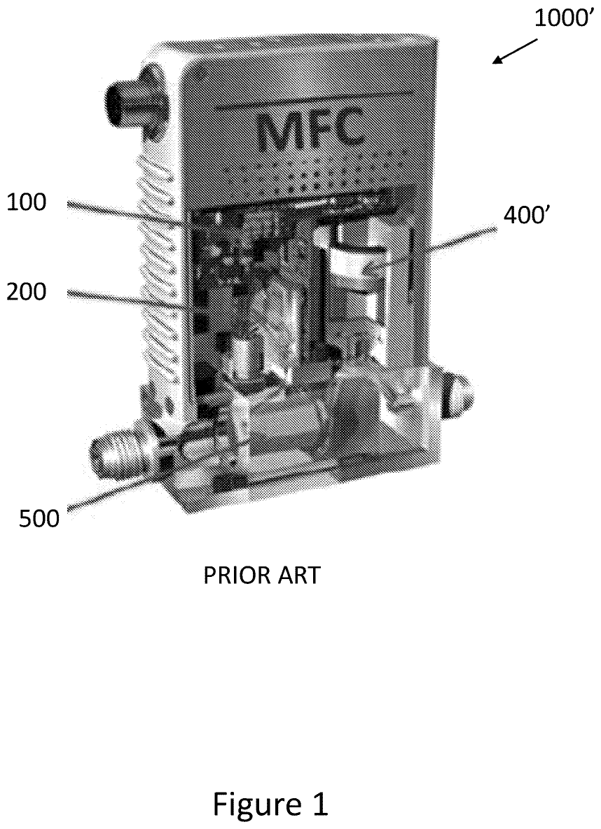

FIG. 1 shows a drawing of a prior art MFC 1000a. The MFC 1000′ includes electronics 100, a sensor 200, a prior art control valve 400′ and a bypass 500.

The prior art control valve 400′ for control of gas flow is typically a solenoid activated piston (not shown). The electronics 100 may receive a command to change the flow. Such command may be compared to the sensor reading of the present flow of fluid through the valve 400′. According to the results of the comparison and the settings of the electronics 100, such valves 400′ allow full retraction or extension of the piston, thereby changing the flow of the fluid. However, such flow regulation is limited between two values. Moreover, the movement of the piston is slow and thus arriving at a desired set-point might be undesirably lengthy. If a different flow is required then both the valve 400′ and the electronics 100 need replacing and perhaps the sensor 200 as well, thus entailing replacement of the entire MFC 1000′.

One objective is to provide a simple MFC having improved responsiveness. Another object is to improve ease of adapting a gas line to new desired flow settings. According to one aspect, a fluid-flow control device is provided, comprising: an inlet, an outlet, an actuation mechanism, and a diaphragm;
wherein:
the diaphragm is in direct operational communication with the outlet and/or inlet;
the mechanism comprises a driving piezoelectric component, and the device is configured to allow:
employing the driving piezoelectric component to adjust force exerted on the diaphragm and thereby regulating flow of the fluid through the device within a first rate range.

“Direct operational communication” means that the diaphragm, at some state of employment, is in direct contact with and/or in between the inlet and/or outlet, as will be shown and explained below when describing some embodiments in detail.

JPH04370401 relates to a device through which a fluid can be conveyed. That device includes a nozzle flapper driving mechanism which controls pressure acting on a diaphragm or a piston connected to a valve rod for interrupting communication between an input port and an output port. An electropneumatic regulator is described therein that may control the output pressure by controlling the displacement of the nozzle flapper based on the detected pressure on the output port side.

The nozzle flapper driving mechanism includes a piezoelectric component. However, the diaphragm in JPH04370401 is not in direct communication with the inlet (input port 2 therein) and/or outlet (output port 3 therein). Rather, the diaphragm therein is situated in a control pressure chamber remote from the inlet and outlet, serves to adjust output pressure. Employment of the diaphragm causes the diaphragm to push a piston.

The device described in JPH04370401 does not allow fine tuning the mass flow. We have devised an overall much simpler device for a different purpose of the improved control of flow.

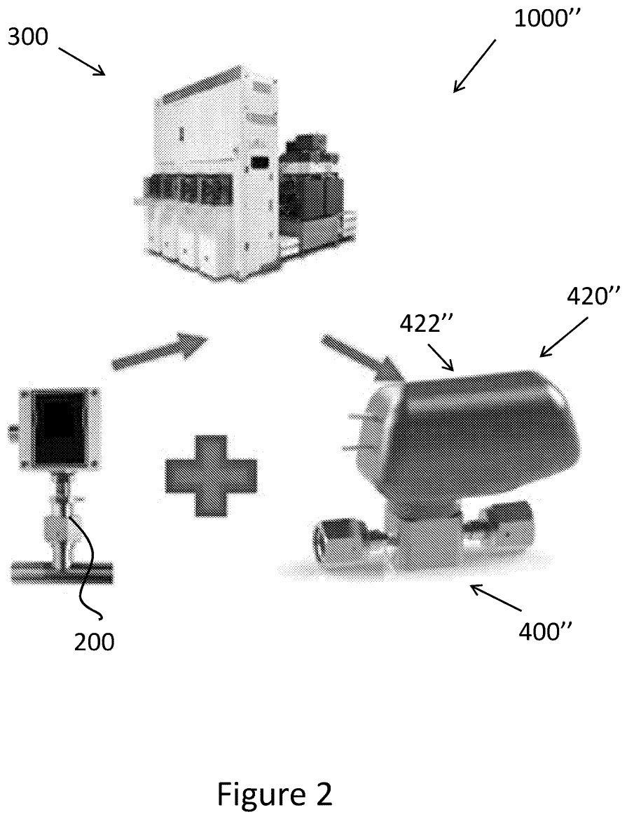

FIG. 2 depicts a schematic block drawing of a MFC 1000″ which includes a valve 400″ with an actuator or actuating mechanism 420″ including a driving piezoelectric component 422″. There is a diaphragm which is in direct operational communication with the outlet and/or inlet (not shown).

The sensor 200 of mass flow, which is typically located downstream of the valve 400″, may report to a PLC (Programmable Logic Controller) 300 that sends commands to the actuator 420″. Changing the MFC 1000″ for new flow regimes can be as easy and simple as changing the driving piezoelectric component 422″ (disconnecting two wires from the driving piezoelectric component 422″ to the actuator 420″) with another of a different range of capabilities, and reusing the PLC 300 and sometimes the sensor 200 as well according to the range of mass flows it can accurately measure.

Generally speaking, there are three types of piezo motors. The most common type is the impact-driven stick-slip piezo motor. A second category consists of the stepper type of piezo motors, also called walking piezo motors, which are typically used for high-force applications. The third type is the ultrasonic or resonant piezo motor. All three types have their specific advantages and uses, which can be explained by examining their working principle in more detail, see for example https://xeryon.com/technology/how-do-piezo-motors-work/.

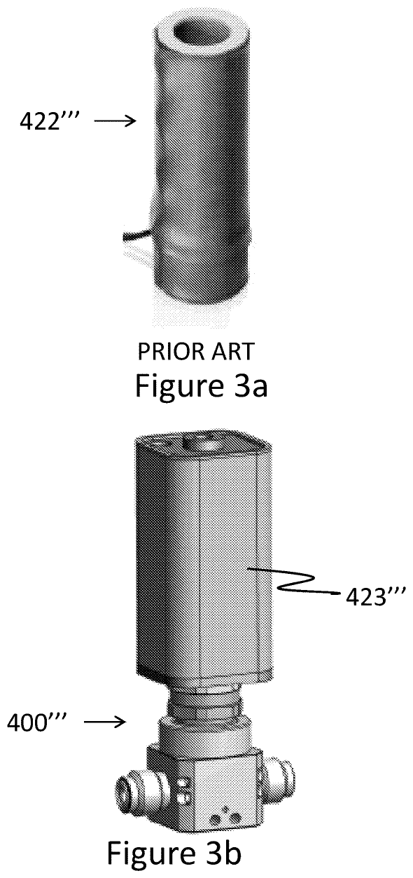

FIG. 3a illustrates a prior art stack-type driving piezoelectric component 422″ that can be used in a device (not shown) for an MFC. FIG. 3b presents a perspective view of a valve 400″ including the stack-type driving piezoelectric component (not shown) situated in an actuator body 423″ and coupled to a diaphragm (not shown) to adjust force exerted on the diaphragm and thereby regulating flow of the fluid through the device within a first rate range.

The advantages of this particular type of driving component for the use of mass flow control are a very fast response rate, typically of several microseconds, and that it is relatively powerful and thus in some embodiments allows complete shut-off of the flow when such is required.

While some commercially available actuating mechanisms are also powerful and fast and thus also are good shut-off valves, those commercial devices lack any stack-type driving piezoelectric component and therefore the flow is only settable in them to zero or to a specific value, whereas our device with this stack-type driving piezoelectric component can allow both powerful and fast shut off and fine adjustment of flow to discrete values up to a maximal flow rate.

The maximal travel distance of the component is typically about 80 μm and the maximum driving force is 9600 N. Once voltage applied to the component stops, the component returns to position of no travel.

Flow-control devices comprising such component may allow omitting an additional shut-off component by enabling complete shut-off in the valve and may allow usage of off-the-shelf sensors for the MFC since the range of mass flow rates (zero to maximum extension of the component) are known in advance.

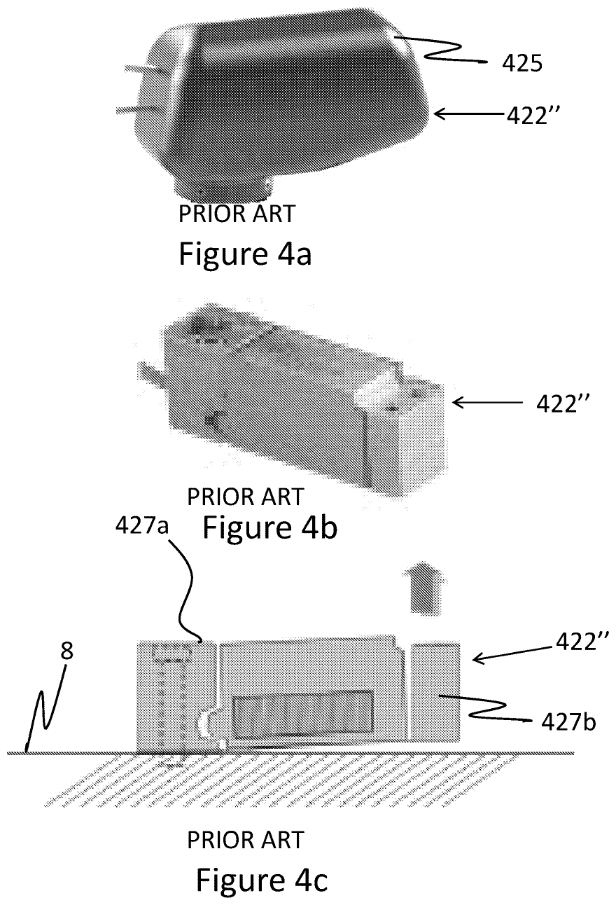

FIG. 4a illustrates a prior art flexure-type driving piezoelectric component 422″ as the component 422″ is typically commercially available, with an elastic cover 425.

FIG. 4b depicts in perspective view the component 422″ with the cover 425 removed. This flexure-type driving piezoelectric component 422″ is in the shape of a cantilever, i.e., elongated and having a free first end 427b.

FIG. 4c illustrates in side view the movement of the prior art driving piezoelectric component 422″ anchored at a second end 427a to a surface 8. The anchorage acts as a fulcrum for a lever that can deflect at the free end 427b.

This component also has an extremely fast response and may allow complete shut-off. The maximum travel distance is considerably longer than that of the stack-type driving piezoelectric component, typically 400 micrometres, and in this respect may be more suitable for many actuators. On the other hand, the maximum driving force is less at 150N. Thus in some applications requiring extremely high reliability an additional component may be added to the actuator to complete shut-off. Once voltage applied to the component stops, the component returns to position of no travel.

Such flexure-guided, lever amplified components are typically very compact, thus helping to minimize the size of gas cabinets where size can be an especially important consideration. The flexure-type components typically have high positioning accuracy with a resolution in the sub-nanometre range; together with their responsiveness they are well suited for both dynamic and static applications.

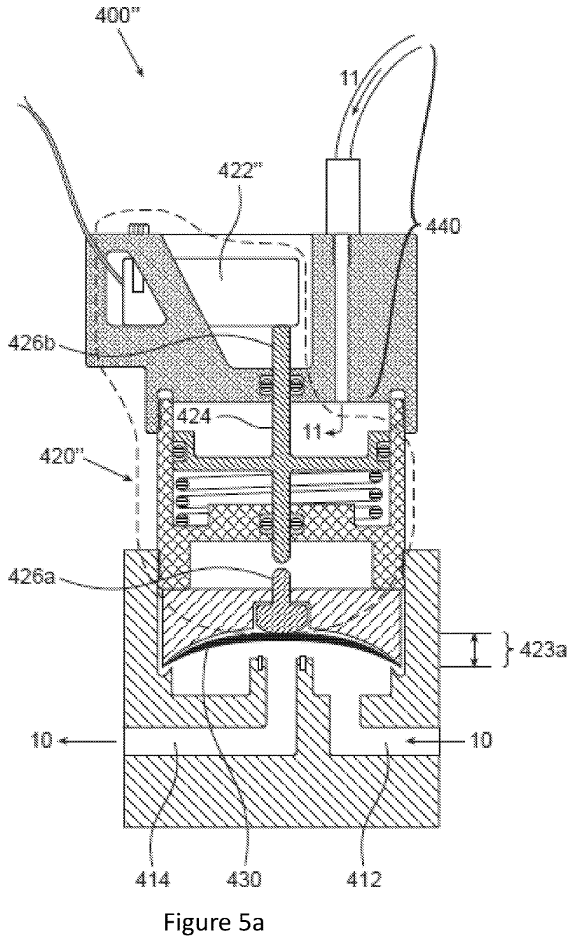

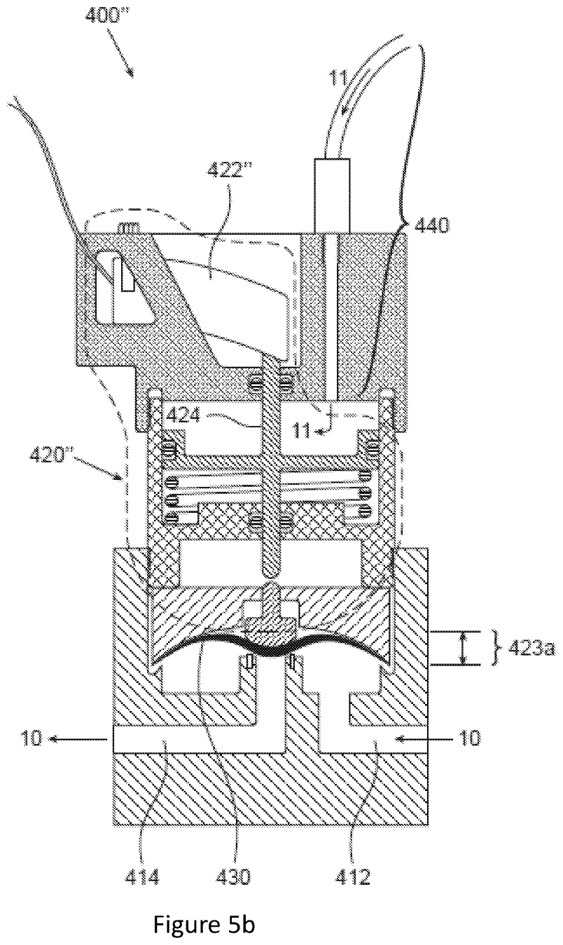

We now discuss some embodiments in greater detail. FIG. 5a depicts, in a side view, a normally open [NO] MFC device 400″ comprising a driving flexure-type piezoelectric component 422″ as also shown in FIGS. 4a-4c, which is part of an actuation mechanism 420″ for the device 400″. The device 400″ is shown in the FIG. 5a in an open state, wherein the piezoelectric component 422″ is at rest. The process fluid-mass flow control device 400″ also includes an inlet 412, an outlet 414, and a diaphragm 430. The diaphragm 430 is in direct operational communication with the outlet 412.

Note that in other embodiments the diaphragm may be in direct communication with the inlet or the inlet and the outlet. The device 400″ may employs the driving piezoelectric component 422″ to adjust force exerted on the diaphragm 430. Thereby, the driving piezoelectric component 422″ regulates flow of the process fluid 10 through the device 400″ within a first rate range 423a.

The device 400″ is shown in FIG. 5b in a closed state, wherein a voltage is applied across the piezoelectric component 422″, and the diaphragm closes outlet 414.

The mechanism 420″ further comprises a non-piezoelectric driving component, a piston 424, in direct operational communication with the diaphragm 430. Thus, the device 400″ may employs the driving piezoelectric component 422″ to adjust force exerted on the non-piezoelectric driving component 424. The non-piezoelectric driving component 424 subsequently applies force on the diaphragm 430 and thereby reduces flow of the fluid 10 through the device 400″.

In other words, the application of voltage on the piezoelectric component 422″ drives it to push a piston 424, which in turn pushes the diaphragm 430. The diaphragm 430, at this state of employment, is in direct contact with the outlet 414.

In addition, the device 400″ further comprises pneumatic means 440 for applying force on the non-piezoelectric driving component 424, thereby shutting flow throughout the device 400″.

Note that the piston 424 has a first end 426a in contact with the diaphragm and a second end 426b in contact with the piezoelectric driving component 422″.

In particular, the second end 426b in contact with the free end 427b of the piezoelectric driving component 422″.

The second end 426b is preferably positioned relative to the flexure-type piezoelectric component 422″ right under the tip of the free end 427b of the component 422″. The length of the piston is parallel to the direction in which it is intended to travel and is also in the general direction of the flexion of the component 422″. Thus the application of voltage to the piezoelectric component 422″ causes maximum movement of the piston 424 and provides a particularly quick and sensitive mass flow adjustment.

The embodiment described in FIGS. 5a and 5b, and indeed other embodiments described herein, have a markedly simple structure and serve for adjustment of mass flow. The driving piezoelectric component 422″ is, for example, flexure-guided, lever amplified which may be particularly suitable for use in driving mass flow adjustment in MFC systems that need to be compact. In addition, the device 400″ is built to allow the diaphragm 430 to be subjected to air pressure to shut-off the flow. In other embodiments, the shut-off capability is provided by electrically activated non-piezoelectric mechanical components which may be included in the device.

Note that employment of the piezoelectric component 422″ alone might not cause the device 400″ to assume a closed state but rather to cause the mass flow via the device 400″to decrease in direct proportion to the voltage that is applied to the piezoelectric component 422″.

The device 400″ is configured to allow air pressure from pressurized air 11 impinging on the piston 424 to apply pressure on the diaphragm 430. The combined forces of the piezoelectric component 430 and the pressurized air 11 may be used to shut off the flow of the process fluid 10. In some embodiments

Pneumatic means 440 are employed only for shutting off the flow. In some embodiments only pneumatic means 440 are employed for shutting off the flow.

At present I believe that these embodiments operate best, but the other embodiments are also satisfactory.

In some other NO embodiments the piezoelectric component is in direct communication with the diaphragm, i.e., the piston is eliminated.

Some embodiments are configured to allow the piezoelectric component to restrict flow of pressurized air and thereby regulate flow of the fluid through the device. For example, pneumatic means can include at least one conduit via which air is supplied to the diaphragm's surface, and the driving piezoelectric component may be employed to move into the conduit and create dead volumes/turbulence therein, thereby reducing the pressure on the diaphragm and allowing an increase of the flow.

Some device embodiments are normally closed (NC). Some of these NC devices include pneumatic means for applying force on the non-piezoelectric driving component (such as a piston). The device may employ the piezoelectric component to allow flow of pressurized air via pneumatic means to the non-piezoelectric driving component and thereby allow flow of the fluid through the device.

The device embodiments may further comprise means for measuring a first location of the piston. According to the measured location the driving piezoelectric component may be employed to adjust the location of the piston to a second predetermined location. Thus, the device adjusts the flow of the fluid through the device to a predetermined desired flow.

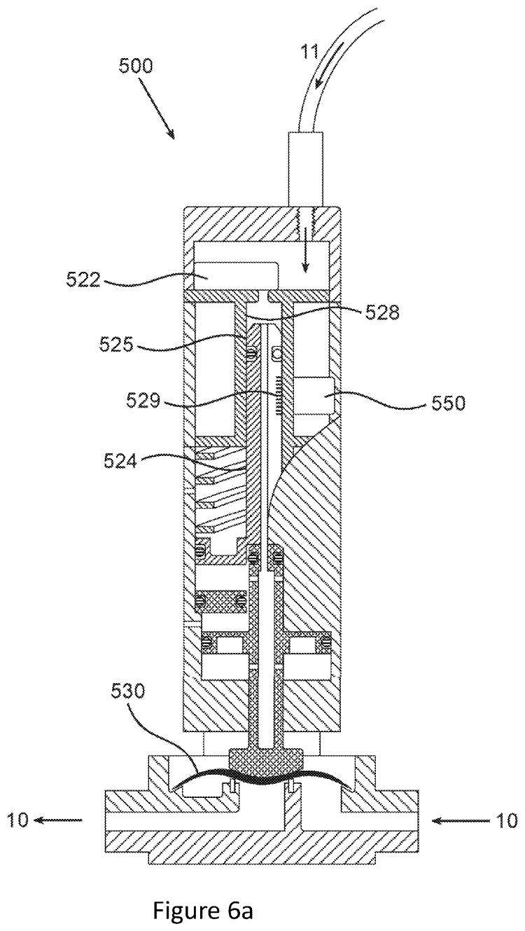

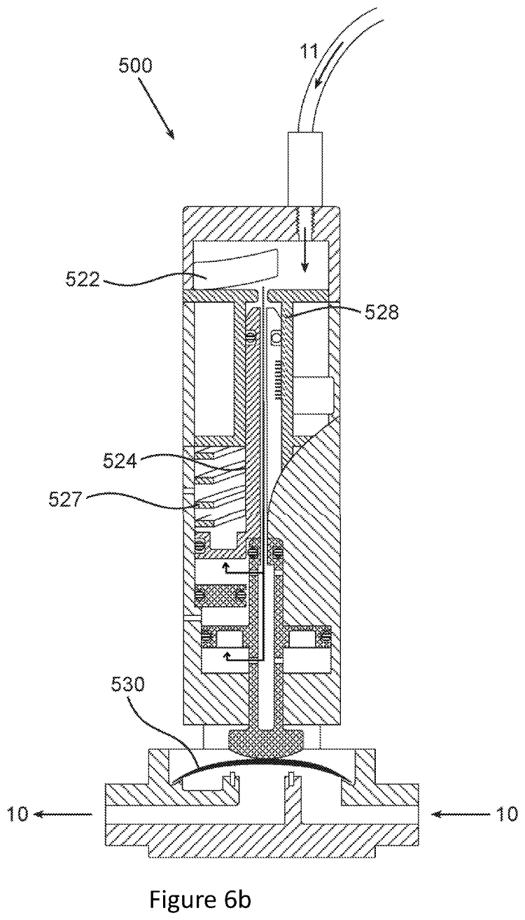

An example of such embodiment is depicted in FIG. 6a. The device 500 is normally closed, as shown in FIG. 6a. The piston 524 is hollow and has a top part 525, adjacent to the driving piezoelectric component 522, that is snugly enclosed in a barrel 528. When the driving piezoelectric component 522 is not employed, i.e., no voltage is applied thereto, the driving piezoelectric component 522 blocks the barrel 528 and thus prevents passage of pressurized air 11 via the piston 524.

As shown in FIG. 6b, when the driving piezoelectric component 522 is employed, the driving piezoelectric component 522 warps and thereby the barrel is no longer blocked and pressurized air 11 may enter the barrel 528 and pass throughout the hollow piston 524. The pressurized air 11 may then push against a spring 527 that is pressing the piston 524 against the diaphragm 530 and thus allow flow of process fluid through the device 500.

The piston 524 has gradations 529 marked there along, that are read by an encoder 550 that can translate a particular gradation to a particular flow.

According to the reading of the gradations the encoder 550 commands the driving piezoelectric component 522 to increase or decrease the entrance of pressurized air 11 into the barrel 524. This feedback control may be performed many times to achieve an accurate desired flow, thanks to the extremely fast responsiveness of the driving piezoelectric component 522.

The embodiments described above allow continuous control of the flow rather than binary control and may be much more effective in allowing both shutting off flow and flow adjustment.

Some high-purity gas line embodiments comprise such the devices as described above.

The driving piezoelectric component may be selected for example from a group consisting of: stack-type driving piezoelectric component; flexure-type driving piezoelectric component, and motor-type driving piezoelectric component.

Any of these devices may in some embodiments further comprise a non-piezoelectric driving component, wherein the device is further configured to allow the driving non-piezoelectric component applying force on the diaphragm and thereby shutting off flow of the fluid through the device.

According to another aspect a kit is provided comprising any of the above devices, and a plurality of interchangeable actuation mechanisms, wherein at least one of the plurality of interchangeable mechanisms comprises the driving piezoelectric component.

### Clarifications About Terminology

In the discussion, unless otherwise stated, adjectives such as “substantially” and “about” that modify a condition or relationship characteristic of a feature or features of an embodiment of the invention, are to be understood to mean that the condition or characteristic is defined to within tolerances that are acceptable for operation of the embodiment for an application for which it is intended.

It should be noted that the term “item” as used herein refers to any physically tangible, individually distinguishable unit of packaged or unpackaged good or goods. Positional terms such as “upper”, “lower” “right”, “left”, “bottom”, “below”, “lowered”, “low”, “top”, “above”, “elevated”, “high”, “vertical” and “horizontal” as well as grammatical variations thereof as may be used herein do not necessarily indicate that, for example, a “bottom” component is below a “top” component, or that a component that is “below” is indeed “below” another component or that a component that is “above” is indeed “above” another component as such directions, components or both may be flipped, rotated, moved in space, placed in a diagonal orientation or position, placed horizontally or vertically, or similarly modified. Accordingly, it will be appreciated that the terms “bottom”, “below”, “top” and “above” may be used herein for exemplary purposes only, to illustrate the relative positioning or placement of certain components, to indicate a first and a second component or to do both.

“Coupled with” means indirectly or directly “coupled with”.

It is important to note that the methods described above are not limited to the corresponding descriptions. For example, the method may include additional or even fewer processes or operations in comparison to what is described herein and/or the accompanying figures. In addition, embodiments of the method are not necessarily limited to the chronological order as illustrated and described herein.

It should be understood that where the claims or specification refer to “a” or “an” element or feature, such reference is not to be construed as there being only one of that element. Hence, reference to “an element” or “at least one element” for instance, may also encompass “one or more elements”.

Unless otherwise stated, the use of the expression “and/or” between the last two members of a list of options for selection indicates that a selection of one or more of the listed options is appropriate and may be made.

It is noted that the term “perspective view” as used herein may also refer to an “isometric view” and vice versa.

It should be appreciated that certain features which are, for clarity, described in the context of separate embodiments, may also be provided in combination in a single embodiment. Conversely, various features, which are, for brevity, described in the context of a single embodiment, example and/or option, may also be provided separately or in any suitable sub-combination or as suitable in any other described embodiment. Certain features described in the context of various embodiments are not to be considered essential features of those embodiments, unless the embodiment, example, and/or option are inoperative without those elements. Accordingly, features, structures, characteristics, stages, methods, modules, elements, entities or systems disclosed herein, which are, for clarity, described in the context of separate examples, may also be provided in combination in a single example. Conversely, various features, structures, characteristics, stages, methods, modules, elements, entities or systems disclosed herein, which are, for brevity, described in the context of a single example, may also be provided separately or in any suitable sub-combination.

It is noted that the term “exemplary” is used herein to refer to examples of embodiments and/or implementations and is not meant to necessarily convey a more desirable use-case.

In alternative and/or other embodiments, additional, fewer, and/or different elements may be used.

Throughout this description, various embodiments may be presented in a range format. It should be understood that the description in range format is merely for convenience and brevity and should not be construed as an inflexible limitation on the scope of the embodiments. Accordingly, the description of a range should be considered to have specifically disclosed all the possible sub ranges as well as individual numerical values within that range. For example, description of a range such as from 1 to 6 should be considered to have specifically disclosed sub ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include—where applicable—any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals there between.

While the aspects have been described with respect to a limited number of embodiments, these should not be construed as scope limitations, but rather as exemplifications of some of the embodiments.

What is claimed is:

1. A process fluid-flow control device comprising: an inlet, an outlet, an actuation mechanism and a diaphragm; wherein: the diaphragm is in direct operational communication with the outlet and/or the inlet; the mechanism comprises a driving piezoelectric component, and the device is configured to allow: employing the driving piezoelectric component to adjust force exerted on the diaphragm and thereby regulating flow of the process fluid through the device within a first rate range; and the mechanism further comprising at least one piston having a first end in contact with the diaphragm and a second end in contact with the piezoelectric driving component, wherein the device is further configured to allow:
employing the driving piezoelectric component to adjust force exerted on the at least one piston, and the at least one piston to apply force on the diaphragm and thereby reducing or shutting off flow of the process fluid through the device.

2. The device of claim 1, wherein the device is normally open, the device further comprising pneumatic means for applying force on the at least one piston, thereby shutting flow through the device.

3. The device of claim 2, the second end in contact with a free end of the piezoelectric driving component, and wherein the piezoelectric driving component is a flexuretype.

4. The device of claim 1, further comprising means for measuring a first location of the piston, and according to the measured location employing the driving piezoelectric component to adjust the location of the piston to a second predetermined location, thereby adjusting flow of the process fluid through the device to a predetermined desired flow.

5. A kit comprising the device of claim 1 and at least one replacement actuation mechanism comprising a replacement driving piezoelectric component, wherein the device is configured to allow employing the at least one replacement driving piezoelectric component to regulate flow of the fluid through the device within a rate range that is not the first rate range.

6. A method for control of fluid flow from an inlet to an outlet, the method comprising:
providing a diaphragm in direct operational communication with the outlet and/or inlet;
providing a driving piezoelectric component; employing the driving piezoelectric component to adjust force exerted on the diaphragm and thereby regulating flow of the fluid through the device within a first rate range; providing at least one piston having a first end in contact with the diaphragm and a second end in contact with the piezoelectric driving component;
employing the driving piezoelectric component to adjust force exerted on the least one piston; and subsequently the at one piston applying force on the diaphragm and thereby reducing or shutting off flow of the fluid through the device.

7. The method of claim 6, further comprising: applying pressurized air on the at least one non-piezoelectric driving component, thereby shutting fluid flow from the inlet to the outlet.

8. The method of claim 6, further comprising: measuring a first location of the non-piezoelectric driving component; and employing the driving piezoelectric component according to the measured location to adjust the location of the piston to a second predetermined location, thereby adjusting the flow of the fluid from the inlet to the outlet to a predetermined desired flow.

9. The method of claim 6, further comprising: measuring a mass flow of the fluid from the outlet; comparing the measured mass flow with a predetermined desired mass flow from the outlet, and employing the driving piezoelectric component to adjust force exerted on the diaphragm and thereby adjust the flow of fluid from the outlet to the desired mass flow.
